(19) United States
(12) Patent Application Publication
(10) Pub. No.: US 2017/0012602 A1
(43) Pub. Date: Jan. 12, 2017

(54) OSCILLATION DEVICE AND PHYSICAL QUANTITY SENSOR

(71) Applicant: DENSO CORPORATION, Kariya-city (JP)

(72) Inventors: Takeru KANAZAWA, Kariya-city (JP); Minekazu SAKAI, Kariya-city (JP)

(21) Appl. No.: 15/201,680

(22) Filed: Jul. 5, 2016

(30) Foreign Application Priority Data
Jul. 7, 2015 (JP) 2015-136348
Jul. 7, 2015 (JP) 2015-136349
Jul. 7, 2015 (JP) 2015-136350

(51) Int. Cl. H03H 9/02; H03H 9/25; G01C 19/5607

(52) U.S. Cl. CPC H03H 9/02551; G01C 19/5607; H03H 9/25

(57) ABSTRACT

An oscillation device includes a vibrator made of a quartz substrate, a vibration substrate coupled to the vibrator and including a peripheral portion surrounding a periphery of the vibrator, a support substrate jointed to the vibration substrate at the peripheral portion of the vibration substrate, a cap layer disposed on an opposite side of the vibration substrate from the support substrate and jointed to the vibration substrate at the peripheral portion of the vibration substrate via a joint. At least one pad electrically connected to the vibration substrate is formed on the cap layer. At least one conductor pattern opposed to the pad is formed on a vibration substrate side surface of the cap layer and is electrically connected to the pad.

### CROSS REFERENCE TO RELATED APPLICATIONS

This application is based on Japanese Patent Applications No. 2015-136350 filed on Jul. 7, 2015, No. 2015-136348 filed on Jul. 7, 2015, and No. 2015-136349 filed on Jul. 7, 2015, disclosures of which are incorporated herein by reference.

### TECHNICAL FIELD

The present disclosure relates to an oscillation device including a quartz vibrator. The oscillation device is applicable to a physical quantity sensor comprising a sensing portion including a quartz vibrator for outputting a sensor signal according to an applied physical quantity.

### BACKGROUND

Because quartz is a favorable piezoelectric material, a quartz vibrator is used as a vibrator in an oscillation device such as an oscillator, a gyro-sensor, a surface acoustic wave element (also called hereinafter a SAW element). For downsizing and cost reduction of an oscillation device used in vacuum, a structure using a wafer level package (also called a WLP) is proposed (see Patent Literatures 1, 2 and 3).

Patent Literature 1: JP 2013-55632A

Patent Literature 2: JP-2010-081127A

Patent Literature 3: JP 2008-244244A

The following describes related arts which do not necessarily constitute prior arts.

In a first example of WLP with a vacuum-sealed quartz vibrator, a wafer for an element (also called hereinafter an element wafer) constituting a sensor substrate is arranged between two wafers for sealing (also called hereinafter sealing wafers) constituting a support substrate and a cap layer. Surfaces of the two sealing wafers on an element wafer side are removed by a predetermined depth to form a vacuum chamber and the quartz vibrator is disposed inside the vacuum chamber. A through hole is formed in the sealing wafer constituting the cap layer and a wiring is provided in the through hole. When the element wafer is arranged between the two sealing wafers, an electrode pad formed in the element wafer is electrically connected to the wiring of the sealing wafer. Through the wiring, the quartz vibrator is electrically connectable to an outside.

A second example of WLP with a vacuum-sealed quartz vibrator includes a first substrate and a second substrate. The first substrate constitutes a support substrate. The second substrate constitutes a cap layer and is jointed to the first substrate. A surface of at least one of the first substrate or the second substrate is removed by a predetermined depth to form a vacuum chamber. The quartz vibrator is disposed inside the vacuum chamber. The quartz vibrator is jointed to the first substrate or the second substrate via a connection electrode and the connection electrode is connected to a penetration electrode formed in the first substrate or the second substrate. Accordingly, various electrodes of the quartz vibrator is electrically connectable to an outside via the penetration electrode.

In a third example of WLP with a vacuum-sealed quartz vibrator, a first substrate constituting a sensor substrate is disposed in a chamber defined by a second substrate constituting a cap layer and a third substrate constituting a support substrate. An electrode disposed on the first substrate is connected to a lead electrode disposed on a rear surface of the second substrate. The lead electrode is led to an outside of the first substrate and connected to a buried wiring which extends from, in the outside of the first substrate, a second substrate side surface of the third substrate to a rear surface of the third substrate, wherein the rear surface is opposite to the second substrate side surface. With this structure, the first substrate disposed inside a vacuum chamber defined by the second and third substrates and the first substrate is electrically connectable to an outside through the electrode, the led wiring and the buried wiring and this electrical connection can be made on a rear side of the third substrate. The second substrate and the third substrate are jointed at outer edge portions thereof via a joint layer. In order to suppress an influence of thermal distortion caused by this jointing, a slit is formed in a third substrate side portion of the second substrate so that the slit is positioned on an inside of the joint layer and on an outside of a connection portion between the led wiring of the second substrate and the buried wiring of the third substrate.

The WLP using a quartz substrate is typically quadrangular due to specificity of quartz crystal growth. Because the same shape facilitates jointing and the like, three quartz substrates may be used for a support substrate, a cap layer and a sensor substrate (the sensor substrate includes a quartz vibrator) and the substrates may be jointed with a metal joint. When the sensor substrate including the quartz vibrator is arranged between the support substrate and the cap layer and are jointed via the metal joint, joint-caused distortion may be generated in the cap layer at the metal joint and electric charges may be induced because the cap layer is made of quartz, which is a piezoelectric material. Thus, electric charges may be generated in a wiring for external connection, a metal joint and the like. This influences a sensor signal and the like and disadvantageously deteriorates sensor accuracy.

The above description refers to, as an example, a device applied with a sensor substrate including a quartz vibrator, specifically, a physical quantity sensor. When a quartz vibrator is applied to an oscillator, the disadvantage relating to the joint-caused distortion may arise also. Specifically, electric charges generated by the joint-caused distortion influences an oscillation frequency of the oscillator and high-accuracy oscillation frequency may not be obtained. That is, the above-described disadvantage may be generated in an oscillator including a quartz vibrator.

Additionally, the above description refers to, as an example, a WLP in which a support substrate and a cap layer made of quartz substrates are jointed to a quartz substrate formed with a quartz vibrator. In that regard, the disadvantage relating to the joint-caused distortion may be generated because the cap layer is made of the quartz substrate. Thus, even if the support substrate is not made of the quartz substrate, the disadvantage may be also generated.

In the WLP using a quartz substrate, a cavity (depression) may be formed on a sensor substrate side surface of the cap layer in order to prevent a quartz vibrator from contacting the cap layer.

However, because a cap layer is made of quartz which is a piezoelectric material, a thin portion of the cap layer resulting from the forming the depression functions as a diaphragm and stress is applied to an electrically connection portion between the cap layer and the sensor substrate. In particular, when the vacuum chamber is provided in the WLP, its outside has an air pressure and thus, a stress caused by a strain resulting from a pressure difference is generated. By these kinds of stress, a piezoelectric effect induces electric charges in the cap layer. This influences a sensor signal and disadvantageously deteriorates sensor accuracy.

In the device described in Patent Literature 3, the slit is formed in the third substrate side (cap layer side) portion of the second substrate to suppress the influence of thermal distortion caused by the jointing. However, when the cap layer functions as a diaphragm, the above-described disadvantage arises due to the influence of the stress at the connection portion between the led wiring and the buried wiring.

The above description refers to, as an example, a device applied with a sensor substrate including a quartz vibrator, specifically, a physical quantity sensor.

When a quartz vibrator is applied to an oscillator also, the disadvantage relating to the stress may arise. Specifically, the stress application influences an oscillation frequency of the oscillator and high-accuracy oscillation frequency may not be obtained. That is, the above-described disadvantage may be generated in an oscillator including a quartz vibrator.

### SUMMARY

In view of the foregoing, it is an object of the present disclosure to suppress accuracy deterioration in an oscillation device having a WLP, in which a vibration substrate including a quartz vibrator is disposed between a support substrate and a cap layer made of a quartz substrate.

In a first aspect of the present disclosure, an oscillation device comprises: a vibrator made of a quartz substrate and configured to vibrate based on voltage application; a vibration substrate coupled to the vibrator and including a peripheral portion surrounding a periphery of the vibrator; a support substrate jointed to the vibration substrate at the peripheral portion of the vibration substrate; a cap layer disposed on an opposite side of the vibration substrate from the support substrate, jointed to the vibration substrate at the peripheral portion of the vibration substrate via a joint, and provided with at least one pad electrically connected to the vibration substrate; and at least one conductor pattern opposed to the pad, formed on a vibration substrate side surface of the cap layer, and electrically connected to the pad.

In the above structure, the conductor pattern opposed to the pad is formed on the cap layer and the pad is electrically connected to the conductor pattern. Therefore, positive and negative electric changes generated in front and rear surfaces of the cap layer can be extracted into the pad and the conductor pattern and the positive and negative electric changes can be coupled and cancelled out in the pad and the conductor pattern. Accordingly, even when the joint-caused distortion at the joint induces electric charges, its influence on a pad for external connection, for example, its influence on a sensor signal, can be suppressed and accuracy deterioration can be suppressed.

In a second aspect of the present disclosure, an oscillation device comprises: a vibrator made of a quartz substrate and configured to vibrate based on voltage application; a vibration substrate coupled to the vibrator and including a peripheral portion surrounding a periphery of the vibrator; a support substrate jointed to the vibration substrate at the peripheral portion of the vibration substrate; a cap layer disposed on an opposite side of the vibration substrate from the support substrate, jointed to the vibration substrate at the peripheral portion of the vibration substrate via a metal joint, and provided with at least one pad electrically connected to the vibration substrate; and an electric charge extraction wiring connected to the metal joint to extract electric charges in the metal joint.

In the above structure, electric charges included in the cap layer due to the joint-caused distortion can be extracted to an outside of, for example, a physical quantity sensor, via the electric charge extraction wiring. Therefore, an influence of electric charges resulting from the joint-caused distortion on a sensor signal can be suppressed and sensor accuracy deterioration can be suppressed.

In a third aspect of the present disclosure, an oscillation device comprises: a vibrator made of a quartz substrate and configured to vibrate based on voltage application; a vibration substrate coupled to the vibrator and including a peripheral portion surrounding a periphery of the vibrator; a support substrate jointed to the vibration substrate at the peripheral portion of the vibration substrate; a cap layer disposed on an opposite side of the vibration substrate from the support substrate, and jointed to the vibration substrate at the peripheral portion of the vibration substrate via a joint, and provided with at least one pad electrically connected to the vibration substrate; and a groove formed on each of a first surface and a second surface of the cap layer, wherein the first surface of the cap layer faces the vibration substrate and is opposite to the second surface, wherein the groove is disposed on an inside of the joint and surrounds the pad.

In the above structure, in each of the first and second surface of the cap layer, the groove is disposed on the inside of the joint and surrounds the pad. Therefore, even when the cap layer functions as a diaphragm, a portion surrounded by the groove is hardly influenced by stress. Accordingly, electric charges are hardly included in the portion surrounded by the groove. It becomes possible to suppress accuracy deterioration.

### BRIEF DESCRIPTION OF DRAWINGS

The above and other objects, configurations and advantages of the present disclosure will become more apparent from the following detailed description made with reference to the following drawings. In the drawings:

FIG. 1 is a diagram illustrating a front face layout of a physical quantity sensor according to a first embodiment;

FIG. 2 is a sectional view taken along line II-II in FIG. 1;

FIG. 3 is a sectional view taken along line III-III in FIG. 1;

FIG. 4 is a diagram illustrating electric charges when pressure is applied to a quartz substrate;

FIG. 5 is a diagram illustrating a front face layout of a physical quantity sensor according to a modification of the first embodiment;

FIG. 6 is a sectional view taking along line VI-VI in FIG. 5;

FIG. 7 is a diagram illustrating a front face layout of a physical quantity sensor according to a second embodiment;

FIG. 8 is a sectional view taken along line VIII-VIII in FIG. 7;

FIG. 9 is a sectional view taken along line IX-IX in FIG. 7;

FIG. 10 is a diagram illustrating a front face layout of a physical quantity sensor according to a modification of the second embodiment;

FIG. 11 is a sectional view taking along line XI-XI in FIG. 10;

FIG. 12 is a diagram illustrating a front face layout of a physical quantity sensor according to a third embodiment;

FIG. 13 is a sectional view taken along line XIII-XIII in FIG. 12;

FIG. 14 is a sectional view taken along line XIVI-XIV in FIG. 12; and

FIG. 15 is a diagram illustrating a front face layout of a physical quantity sensor according to a modification of the third embodiment.

### DETAILED DESCRIPTION

Embodiments will be described with reference to the drawings. In the below embodiments, like reference are used to refer to like parts.

### First Embodiment

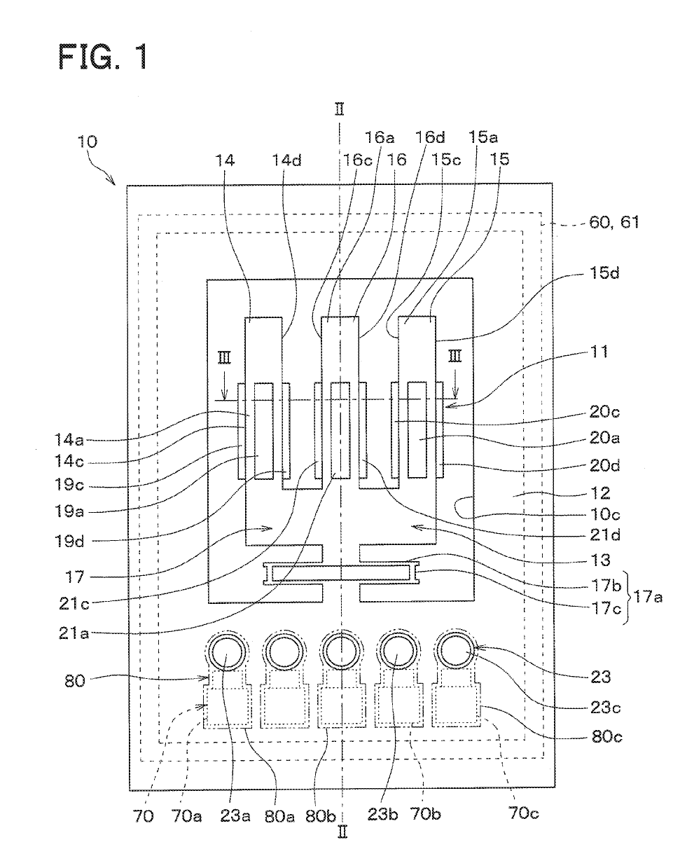

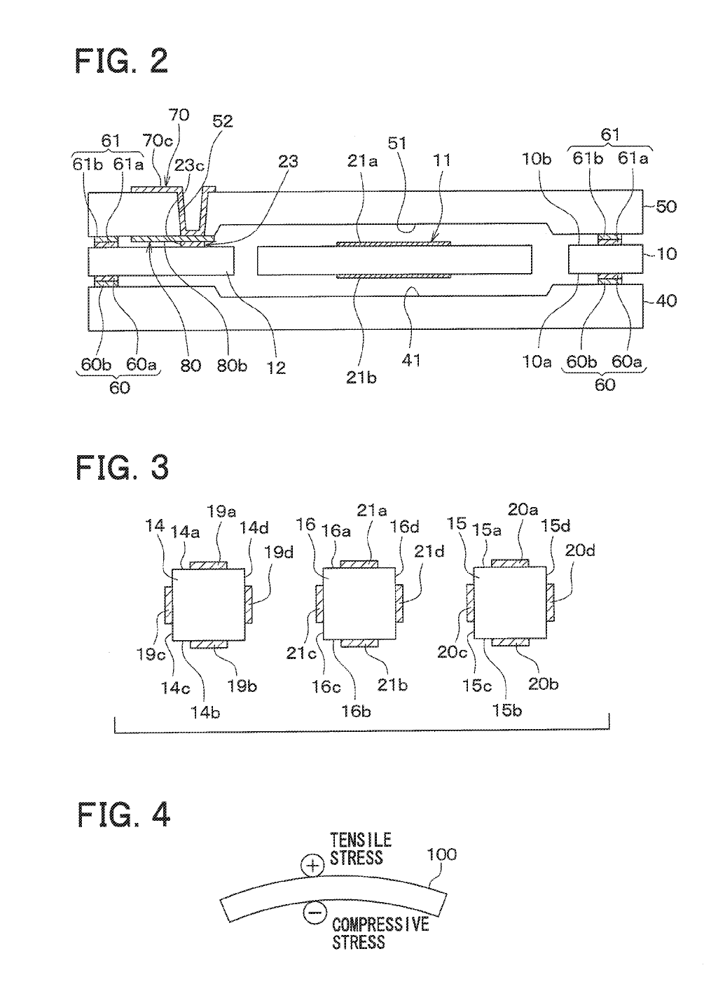

A first embodiment will be described with reference to FIG. 1 to FIG. 3. As shown in FIG. 1 and FIG. 2, a physical quantity sensor has a WLP structure including a sensor substrate 10, a support substrate 40 and a cap layer 50. A first surface of the sensor substrate 10 is called a rear surface 10a. A second surface opposite to the first surface is called a front surface 10b. The support substrate 40 is jointed to the rear surface 10a of the sensor substrate 10 via a metal joint 61. The cap layer 50 is jointed to the front surface 10b of the sensor substrate 10 via a metal joint 61. The sensor substrate 10 is disposed between the support substrate 40 and the cap layer 50 to form a vacuum chamber inside of which a sensing portion 11 is disposed. In the present embodiment, all of the sensor substrate 10, the support substrate 40 and the cap layer 50 are made from quartz substrates, which are piezoelectric substrates. However, it may be sufficient that at least the sensor substrate 10 and the cap layer 50 be made from quartz substrates. The support substrate 40 may be made of other materials such as glass.

As shown in FIG. 1, the sensor substrate 10 includes the sensing portion 11 and a peripheral portion 12 surrounding a periphery of the sensing portion 11. The sensing portion 11 includes a quartz vibrator 13. In the present embodiment, the quartz vibrator 13 is a tripod turning fork type. However, the quartz vibrator 13 may have other structures including known ones, such as a T turning fork type and an H turning fork type.

The sensing portion 11 is formed by performing a known micro-machine processing on the sensor substrate 10 to form a groove 10c and separating the quartz vibrator 13 from the peripheral portion 12.

The quartz vibrator 13 is constructed such that a first driving piece 14, a second driving piece 15 and a detection piece 16 are supported by a base portion 17 and that the base portion serves as a coupling portion to couple the first driving piece 14, the second driving piece 15 and the detection piece 16 to the peripheral portion 12. Specifically, the quartz vibrator 13 is a tripod turning fork type in which the first and second driving pieces 14, 15 and the detection piece 16 are arranged to protrude from the base portion 17 in the same direction and the detection piece 16 is disposed between the first and second driving pieces 14, 15.

The base portion 17 is formed with a vibration proof portion 17a for absorbing disturbance vibration. The vibration proof portion 17a includes two beam portions 17b and a connection portion 17c connecting the two beam portions 17b. A longitudinal direction of the two beam portions 17b is perpendicular to a longitudinal direction of the first driving piece 14, the second driving piece 15 and the detection piece 16. In this structure, when the disturbance vibration is generated, the beam portions 17b are bent to absorb the disturbance vibration, thereby suppressing an influence on the first driving piece 14, the second driving piece 15 and the detection piece 16.

As shown in FIG. 3, the first driving piece 14 is rectangular in cross section and has a front surface 14a, a rear surface 14b and side surfaces 14c, 14d. The second driving piece 15 is rectangular in cross section and has a front surface 15a, a rear surface 15b and side surfaces 15c, 15d. The detection piece 16 is rectangular in cross section and has a front surface 16a and a rear surface 16b and side surfaces 16c, 16d. The surfaces 14a, 15a, 16a are parallel to a plane direction of the sensor substrate 10.

A driving electrode 19a is formed on the front surface 14a of the first driving piece 14. A driving electrode 19b is formed on the rear surface 14b. Common electrodes 19c, 19d are formed on the side surfaces 14c, 14d. Likewise, a driving electrode 20a is formed on the front surface 15a of the second driving piece 15. A driving electrode 20b is formed on the rear surface 15b. Common electrodes 20c, 20d are formed on the side surfaces 15c, 15d. Additionally, a detection electrode 21a is formed on the front surface 16a of the detection piece 16. A detection electrode 21b is formed on the rear surface 16b. Common electrodes 21c, 21d are formed on the side surfaces 16c, 16d.

In the present embodiment, the sensing portion 11 is constructed to include the first and second driving pieces 14, 15, the detection piece 16, the driving electrodes 19a, 19b, 20a, 20b, the detection electrodes 21a, 21b, and the common electrodes 19c, 19d, 20c, 20d, 21c, 21d.

As shown in FIG. 1, the peripheral portion 12 is formed with multiple pad connection portions 23 which are electrically connected via wiring layers or the like (not shown) to the driving electrodes 19a, 19b, 20a, 20b, the detection electrodes 21a, 21b, the common electrodes 19c, 19d, 20c, 20d, 21c, 21d.

The pad connection portions 23 include a power supply pad connection portion 23a for driving voltage application, an output pad connection portion 23b for sensor output, and a ground pad connection portion 23c for ground electric potential application. The respective pad connection portions 23 are connected to wiring patterns led form the above described various electrodes 19a to 19d, 20a to 20d, 21a to 21d. For example, the respective pad connection portions 23 are formed as part of wiring patterns.

For example, the driving electrodes 19a, 19b, 20a, 20b are connected to the power supply pad connection portions 23a. The detection electrodes 21a, 21b are connected to the output pad connection portions 23b. The common electrodes 19c, 19d, 20c, 20d, 21c, 21d are connected to the ground pad connection portion 23c. In FIG. 1, each portion of the sensor substrate 10 is shown by solid line and portions of the cap layer 50 are shown by broken line. The number of pad connection portions 23 shown in the drawings is merely an example. The number is not limited to those shown in the drawings.

A joint pattern 60a constituting part of the metal joint 60 is formed on the rear surface 10a of the sensor substrate 10 so as to surround the sensing portion 11 by one round. A joint pattern 61a constituting part of the metal joint 61 is formed on the front surface 10b of the sensor substrate 10 so as to surround the sensing portion 11 by one round. These joint patterns 60a, 60b are made of a metal material which provides metal eutectic bonding. The metal material is, for example, gold (Au), copper (Cu) etc.

The support substrate 40 is made of, for example, a quartz substrate. A cavity 41 is formed on, of a surface of the support substrate 40 on a sensor substrate 10 side, a portion corresponding to the sensing portion 11. This portion is inside a portion corresponding to the peripheral portion 12. Because of the cavity 41, the quartz vibrator 13 is prevented from contacting the support substrate 40. The joint pattern 60b constituting part of the metal joint 60 is formed on, of the support substrate 40, a portion corresponding to the peripheral portion 12 so that the joint pattern 60b surrounds the sensing portion 11 by one round. The joint pattern 60b is made of, for example, a metal material providing metal eutectic bonding and is formed using, for example, gold, copper etc. The joint pattern 60b has the same pattern as the joint pattern 60a formed on the rear surface 10a of the sensor substrate 10. By metal-jointing the joint patterns 60a, 60b, the metal joint 60 is formed and the joint between the support substrate 40 and the sensor substrate 10 is made

The cap layer 50 is made of, for example, a quartz substrate. A cavity 51 is formed on, of a surface of the cap layer 50 on a sensor substrate 10 side, a portion corresponding to the sensing portion 11. This portion is inside other portions corresponding to the peripheral portion 12. Because of the cavity 51, the quartz vibrator 13 is prevented from contacting the cap layer 50. The joint pattern 61b constituting part of the metal joint 61 is formed on, of the cap layer 50, a portion corresponding to the peripheral portion 12 so that the joint pattern 61b surrounds the sensing portion 11 by one round. The joint pattern 61b is made of, for example, a metal material providing metal eutectic bonding and is formed using, for example, gold, copper etc. The joint pattern 61b has the same pattern as the joint pattern 61a formed on the front surface 10b of the sensor substrate 10. By metal-jointing the joint patterns 61a, 61b, the metal joint 61 is formed and the joint between the cap layer 50 and the sensor substrate 10 is made.

A through-hole 52 is formed in the cap layer 50 at a position corresponding to each pad connection portion 23. A pad 70 extends from an inside of the through-hole 52 to a surface of the cap layer 50 on an opposite side from the sensor substrate 10. The pads 70 correspond to respective pad connection portions 23 and include a power supply pad 70a for voltage application, an output pad 70b for sensor output, and the ground pad 70c for ground electric potential application. The pads 70 are separated from one another and electrically connected to corresponding pad connection portions 23. Each pad 70 is electrically connected to a corresponding pad connection portion 23.

The pad 70 is formed by, for example, forming the through-hole 52 by etching the cap layer 50 or the like, and then, forming a conductive layer made of an electrode material such as aluminum (Al) or the like on a region including the inside of the through-hole 52. The pads 70 may be formed before or after jointing the cap layer 50 and the sensor substrate 10.

As shown by two-dotted chain line in FIG. 1, a conductor pattern 80 opposed to each pad 70 is formed on a surface of the cap layer 50 on a sensor substrate 10 side. Specifically, the conductor patterns include a power supply pattern 80a arranged to be opposed to the power supply pad 70a, an output pattern 80b arranged to be opposed to the output pad 70b, and a ground pattern 80c arranged to be opposed to the ground pad 70c. It may be preferable that these conductor patterns 80 have the same layout as the pads 70 when viewed in a direction perpendicular to the surface of the cap layer 50. The conductor patterns 80 are electrically connected to the pads 70 through the through-holes 52.

The conductor patterns 80 are made of, for example, the same material as the pads 70 (e.g., aluminum) and are formed by patterning after forming a conductor layer on the surface of the cap layer 50.

The physical quantity sensor of the present embodiment has the above-described structure. This physical quantity sensor constitutes, for example, a gyro-sensor that performs angular velocity detection using the quartz vibrator 13 formed in the sensing portion 11. An operation of the physical quantity sensor will be described below.

When driving signals (carrier waves) different in phase by 180 degrees are applied to the driving electrodes 19a, 19b of the first driving piece 14 and the driving electrodes 20a, 20b of the second driving piece 15, the first and second driving pieces 14, 15 vibrate in left and right directions of the sheet of FIG. 1 and the detection piece 16 is substantially in a stationary state. In this case, when the angular velocity around an axis perpendicular to the surface of the sensor substrate 10 is applied, the detection piece 16 vibrates in the left and right directions of the sheet of FIG. 1 in accordance with the angular velocity. Accordingly, electric charges are generated in the detection piece 16 based on a piezoelectric effect and are outputted via the detection electrodes 21a, 21b. The sensor output based on the generation of the electric charges provides a sensor signal and the angular velocity is detected.

The angular velocity is detectable in this way. In this connection, because the cap layer 50 is made of a quartz substrate serving as a piezoelectric substrate, a joint-caused distortion is generated in the joint which joints the cap layer 50 and the sensor substrate 10 via the metal joint 61. Because of this joint-caused distortion, electric charges are induced in the cap layer 50. In general, as shown in FIG. 4, when pressure is applied to a quartz substrate 100, electric charges are generated in front and rear sides of the quartz substrate 100. As shown in FIG. 4, when the pressure is applied to the rear surface, negative electric charges are induced in the rear side having a compressive stress and positive electric charges are induced in the front side having a tensile stress. When the quartz substrate 100 is pulled from the rear surface, negative electric charges are induced in the front side and positive electric charges are induced in the rear side. In the quartz vibrator 13, the driving electrodes 19a, 19b, 20a, 20b are attached to the first driving piece 14 and the second driving piece 15, for voltage application. Accordingly, by using an inverse piezoelectric effect to vibrate the first driving piece 14 and the second driving piece 15, it becomes possible to vibrate at an intended frequency. In this regard, however, when the cap layer 50 is also made of a quartz substrate, the joint-caused distortion generates electric charges.

For addressing this, in the present embodiment, the conductor pattern 80 opposed to the pad 70 is formed on the cap layer 50 and the pad 70 and the conductor pattern 80 are electrically connected to each other. Accordingly, the positive and negative electric charges generated in the front and rear surfaces of the cap layer 50 are extracted into the pad 70 and the conductor pattern 80 and the positive and negative electric charges can be coupled and cancelled in these pad 70 and conductor pattern 80. Therefore, even when the joint-caused distortion at the metal joint 61 induces the electric charges, an influence on pads 70 for external connection, for example, influence on a sensor signal, can be suppressed and the deterioration of sensor accuracy can be suppressed.

### Modification of First Embodiment

The present embodiment is a modification of the first embodiment in structures of the pads 70 and the conductor patterns 80. With regard to other points, the present embodiment is substantially the same as the first embodiment. A difference from the first embodiment will be described.

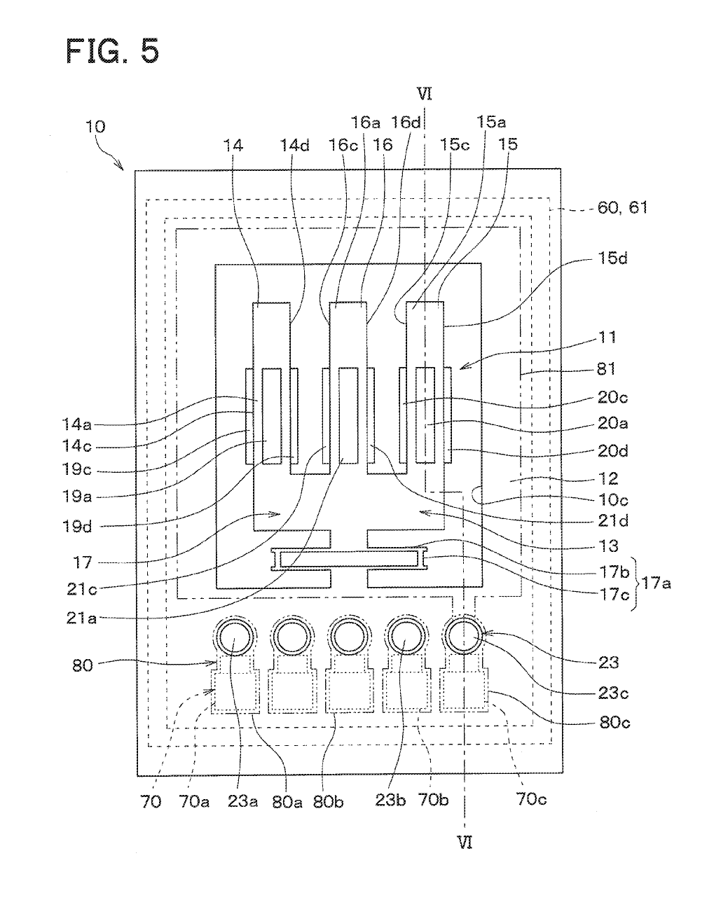

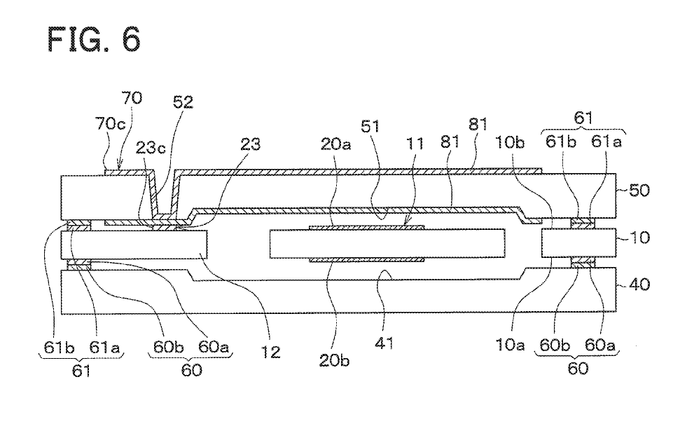

In the present embodiment, as shown in FIG. 5 and FIG. 6, a cover pattern 81 performing the same function as the conductor pattern 80 is formed on the cap sensor 50 at a position corresponding to the sensing portion 11. Specifically, as shown by two-dotted dashed line in FIG. 5, the cover pattern 81 is larger than regions corresponding to the sensing portion 11 and the groove 10c. The cover pattern 81 is connected to the ground pad 70c.

The cover pattern 81 is disposed on both of the front and rear surfaces of the cap layer 50, that is, on a sensor substrate 10 side surface and an opposite surface. The cover patterns 81 disposed on both of the front and rear surfaces are opposed to each other and have the same pattern.

The cover patterns 81 having the same pattern are formed on both of the front and rear surfaces of the cap layer 50. Accordingly, when the positive and negative electric charges generated in the front and rear surfaces are extracted and led to the ground pad 70c, the positive and negative electric charges are coupled and cancelled. For example, there is a possibility that the cap layer 50 functions as a diaphragm and displaces. In this case, electric charges generated in the cap layer 50 can be extracted. In particular, when the vacuum chamber is formed, a pressure difference with respect to external air pressure facilitates displacement of the cap layer 50, and additionally, when the cavity 51 is formed, the displacement of the cap layer 50 is further facilitated. Therefore, by forming the cover pattern 8, it becomes possible to further improve sensor accuracy. Moreover, when the cover pattern 81 is formed to cover, of the cap layer 50, a portion corresponding to the sensing portion 11 and is connected to the ground pad 70c having the ground potential, it becomes possible to provide a shield effect against noise and the like.

### Other Modifications of First Embodiment

Embodiments are not limited to those illustrated above. Various modifications are possible within the spirit and scope of the present disclosure. For example, although the physical quantity sensor, in particular, the gyro sensor, is illustrated in the above embodiments as an example of an oscillation device including a quartz vibrator, this is merely an example. Technical ideas of the present disclosure are applicable to other physical quantity sensor than the gyro sensor, for example, an acceleration sensor. Structures of the quartz vibrator are not limited to those illustrated in the above embodiments. For example, the physical quantity sensor may be a surface acoustic wave (SAW) element or the like and detect a physical quantity through generating SAW on a surface of a sensor substrate. Additionally, the oscillation device is not limited to physical quantity sensors but may be a crystal oscillator or the like. For example, technical ideas of the present disclosure are applicable to an oscillation device in which a support substrate and a cap layer which is made of a quartz substrate are jointed to a vibration substrate which is made of a quartz substrate and includes a vibrator.

In the above embodiments, the base portion 17 is provided with the vibration proof portion 17a. Alternatively, the vibration proof portion 17a may be omitted.

In the above embodiments, the cover pattern 81 is connected to the ground pad 70c so that, of the conductor pattern 80, a portion arranged to be opposed to the ground pad 70c is connected to the cover pattern 81. Alternatively, a structure of the cover pattern 81 may be independent of the conductor pattern 80, and the cover patterns 81 on the front surface may be electrically connected only to the cover pattern 81 on the rear surface independently of the conductor pattern 80. The cover pattern 81 is, in order to further function as a shield, electrically connected to the ground pattern 80c and the ground pad 70c. Alternatively, the cover pattern 81 may be connected to a different pad 70 or a different conductor pattern 80 opposed to the cover pattern 81.

### Second Embodiment

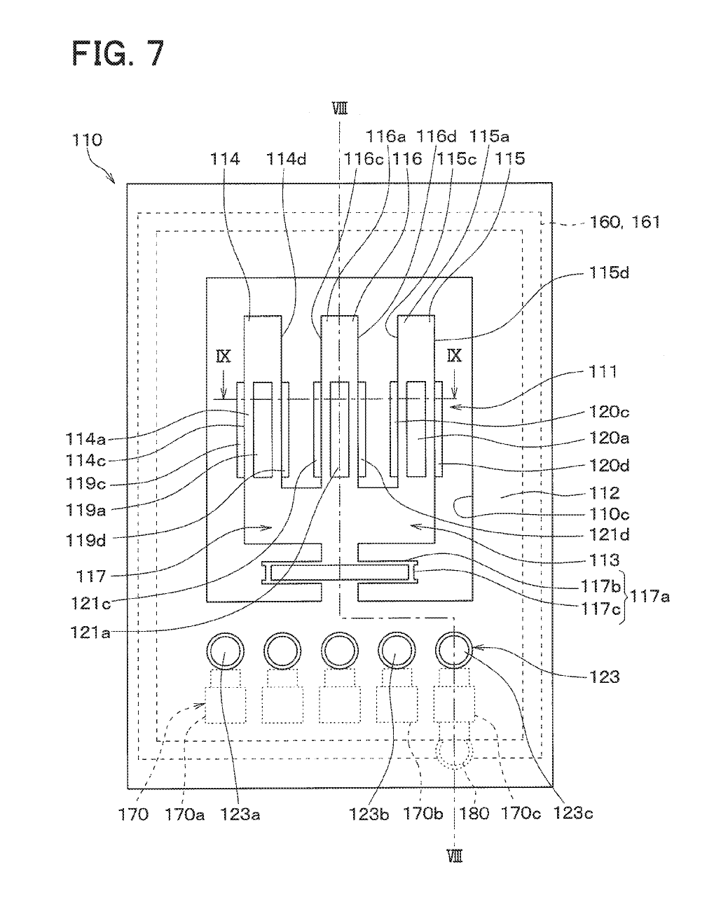

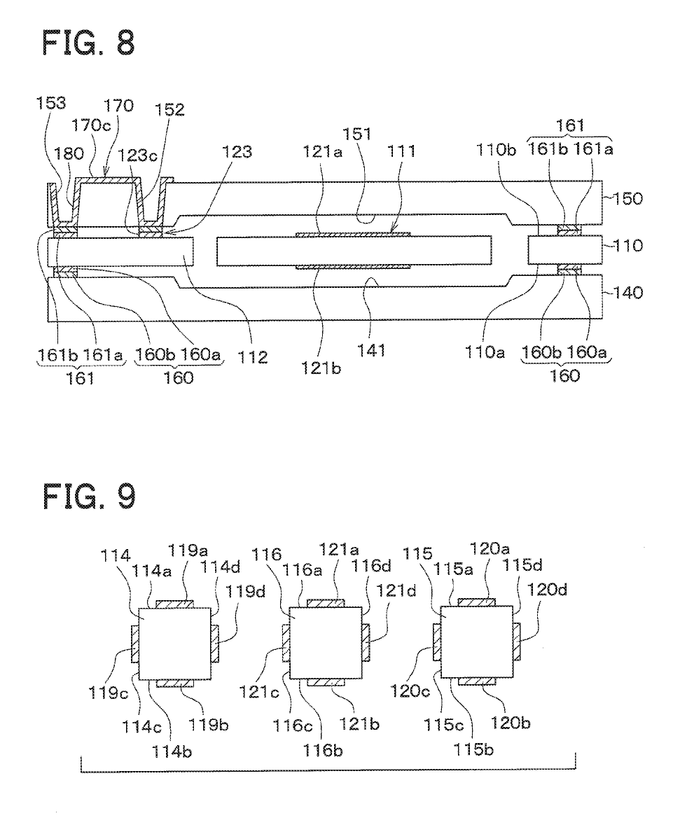

A second embodiment will be described with reference to FIG. 7 to FIG. 9. As shown in FIG. 7 and FIG. 8, a physical quantity sensor has a WLP structure including a sensor substrate 110, a support substrate 140 and a cap layer 150. A first surface of the sensor substrate 110 is called a rear surface 110a. A second surface opposite to the first surface is called a front surface 110b. The support substrate 140 is jointed to the rear surface 110a of the sensor substrate 110 via a metal joint 161. The cap layer 150 is jointed to the front surface 110b of the sensor substrate 110 via a metal joint 161. The sensor substrate 110 is disposed between the support substrate 140 and the cap layer 150 to form a vacuum chamber inside of which a sensing portion 111 is disposed. In the present embodiment, all of the sensor substrate 110, the support substrate 140 and the cap layer 150 are made from quartz substrates, which are piezoelectric substrates. However, it may be sufficient that at least the sensor substrate 110 and the cap layer 150 be made from quartz substrates. The support substrate 140 may be made of other materials such as glass.

As shown in FIG. 7, the sensor substrate 110 includes the sensing portion 111 and a peripheral portion 112 surrounding a periphery of the sensing portion 111. The sensing portion 111 includes a quartz vibrator 113. In the present embodiment, the quartz vibrator 113 is a tripod turning fork type. However, the quartz vibrator 113 may have other structures including known ones, such as a T turning fork type and an H turning fork type.

The sensing portion 111 is formed by performing a known micro-machine processing on the sensor substrate 110 to form a groove 110c and separating the quartz vibrator 113 from the peripheral portion 112.

The quartz vibrator 113 is constructed such that a first driving piece 114, a second driving piece 115 and a detection piece 116 are supported by a base portion 117 and that the base portion serves as a coupling portion to couple the first driving piece 114, the second driving piece 115 and the detection piece 116 to the peripheral portion 112. Specifically, the quartz vibrator 113 is a tripod turning fork type in which the first and second driving pieces 114, 115 and the detection piece 116 are arranged to protrude from the base portion 117 in the same direction and the detection piece 116 is disposed between the first and second driving pieces 114, 115.

The base portion 117 is formed with a vibration proof portion 117a for absorbing disturbance vibration. The vibration proof portion 117a includes two beam portions 117b and a connection portion 117c connecting the two beam portions 117b. A longitudinal direction of the two beam portions 117b is perpendicular to a longitudinal direction of the first driving piece 114, the second driving piece 115 and the detection piece 116. In this structure, when the disturbance vibration is generated, the beam portions 117b are bent to absorb the disturbance vibration, thereby suppressing an influence on the first driving piece 114, the second driving piece 115 and the detection piece 116.

As shown in FIG. 9, the first driving piece 114 is rectangular in cross section and has a front surface 114a, a rear surface 114b and side surfaces 114c, 114d. The second driving piece 115 is rectangular in cross section and has a front surface 115a, a rear surface 115b and side surfaces 115c, 115d. The detection piece 116 is rectangular in cross section and has a front surface 116a and a rear surface 116b and side surfaces 116c, 116d. The surfaces 114a, 115a, 116a are parallel to a plane direction of the sensor substrate 110.

A driving electrode 119a is formed on the front surface 114a of the first driving piece 114. A driving electrode 119b is formed on the rear surface 114b. Common electrodes 119c, 119d are formed on the side surfaces 114c, 114d. Likewise, a driving electrode 120a is formed on the front surface 115a of the second driving piece 115. A driving electrode 120b is formed on the rear surface 115b. Common electrodes 120c, 120d are formed on the side surfaces 115c, 115d. Additionally, a detection electrode 121a is formed on the front surface 116a of the detection piece 116. A detection electrode 121b is formed on the rear surface 116b. Common electrodes 121c, 121d are formed on the side surfaces 116c, 116d.

In the present embodiment, the sensing portion 111 is constructed to include the first and second driving pieces 114, 115, the detection piece 116, the driving electrodes 119a, 119b, 120a, 120b, the detection electrodes 121a, 121b, and the common electrodes 119c, 119d, 120c, 120d, 121c, 121d.

As shown in FIG. 7, the peripheral portion 112 is formed with multiple pad connection portions 123 which are electrically connected via wiring layers or the like (not shown) to the driving electrodes 119a, 119b, 120a, 120b, the detection electrodes 121a, 121b, the common electrodes 119c, 119d, 120c, 120d, 121c, 121d.

The pad connection portions 123 include a power supply pad connection portion 123a for driving voltage application, an output pad connection portion 123b for sensor output, and a ground pad connection portion 123c for ground electric potential application. The respective pad connection portions 123 are connected to wiring patterns led form the above described various electrodes 119a to 119d, 120a to 120d, 121a to 121d. For example, the respective pad connection portions 123 are part of wiring patterns.

For example, the driving electrodes 119a, 119b, 120a, 120b are connected to the power supply pad connection portions 123a. The detection electrodes 121a , 121b are connected to the output pad connection portions 123b. The common electrodes 119c, 119d, 120c, 120d, 121c, 121d are connected to the ground pad connection portion 123c. In FIG. 7, each portion of the sensor substrate 110 is shown by solid line and portions of the cap layer 150 are shown by broken line. The number of pad connection portions 123 shown in the drawings is merely an example. The number is not limited to those shown in the drawings.

A joint pattern 160a constituting part of the metal joint 160 is formed on the rear surface 110a of the sensor substrate 110 so as to surround the sensing portion 111 by one round. A joint pattern 161a constituting part of the metal joint 161 is formed on the front surface 110b of the sensor substrate 110 so as to surround the sensing portion 111 by one round. These joint patterns 160a, 160b are made of a metal material which provides metal eutectic bonding. The metal material is, for example, gold (Au), copper (Cu) etc.

The support substrate 140 is made of, for example, a quartz substrate. A cavity 141 is formed on, of a surface of the support substrate 140 on a sensor substrate 110 side, a portion corresponding to the sensing portion 111. This portion is inside a portion corresponding to the peripheral portion 112. Because of the cavity 141, the quartz vibrator 113 is prevented from contacting the support substrate 140. The joint pattern 160b constituting part of the metal joint 160 is formed on, of the support substrate 140, a portion corresponding to the peripheral portion 112 so that the joint pattern 160b surrounds the sensing portion 111 by one round. The joint pattern 160b is made of, for example, a metal material providing metal eutectic bonding and is formed using, for example, gold, copper etc. The joint pattern 160b has the same pattern as the joint pattern 160a formed on the rear surface 110a of the sensor substrate 110. By metal-jointing the joint patterns 160a, 160b, the metal joint 160 is formed and the joint between the support substrate 140 and the sensor substrate 110 is made.

The cap layer 150 is made of, for example, a quartz substrate. A cavity 151 is formed on, of a surface of the cap layer 150 on a sensor substrate 110 side, a portion corresponding to the sensing portion 111. This portion is inside other portions corresponding to the peripheral portion 112. Because of the cavity 151, the quartz vibrator 113 is prevented from contacting the cap layer 150. The joint pattern 161b constituting part of the metal joint 161 is formed on, of the cap layer 150, a portion corresponding to the peripheral portion 112 so that the joint pattern 161b surrounds the sensing portion 111 by one round. The joint pattern 161b is made of, for example, a metal material providing metal eutectic bonding and is formed using, for example, gold, copper etc. The joint pattern 161b has the same pattern as the joint pattern 161a formed on the front surface 110b of the sensor substrate 110. By metal-jointing the joint patterns 161a, 161b, the metal joint 161 is formed and the joint between the cap layer 150 and the sensor substrate 110 is made.

A through-hole 152 is formed in the cap layer 150 at a position corresponding to each pad connection portion 123. A pad 170 extends from an inside of the through-hole 152 to a surface of the cap layer 150 on an opposite side from the sensor substrate 110. The pads 170 correspond to respective pad connection portions 123 and include a power supply pad 170a for voltage application, an output pad 170b for sensor output, and the ground pad 170c for ground electric potential application. The pads 170 are separated from one another and electrically connected to corresponding pad connection portions 123. Each pad 170 is electrically connected to a corresponding pad connection portion 123.

The pad 170 is formed by, for example, forming the through-hole 152 by etching the cap layer 150 or the like, and then, forming a conductive layer made of an electrode material such as aluminum (Al) or the like on a region including the inside of the through-hole 152. The pads 170 may be formed before or after jointing the cap layer 150 and the sensor substrate 110.

A through-hole 154 is formed in the cap layer 150 at a position corresponding to the metal joint 161. An electric charge extraction wiring 180 extends from an inside of the through-hole 152 to a surface of the cap layer 150 on an opposite side from the sensor substrate 110. The electric charge extraction wiring 180 is a wiring for extracting charges that are generated in the sensor substrate 110 made of a quartz substrate by the joint-caused distortion. The electric charge extraction wiring 180 is connected to a part having a ground electric potential. In the present embodiment, the electric charge extraction wiring 180 is coupled to the ground pad 170c. When the ground pad 170c is connected to an external part having a ground electric potential via a bonding wire (not shown), the electric charge extraction wiring 180 has the ground electric potential.

The electric charge extraction wiring 180 may be provided separately from the pad 170. However, it may be preferable that, by using a conductive layer used for forming the pad, the electric charge extraction wiring 180 be formed at the same time as the pad 170. In this case, because the electric charge extraction wiring 180 and the pad 170 are formed in the same manufacturing step, manufacturing processes can be simplified.

The physical quantity sensor of the present embodiment has the above-described structure. This physical quantity sensor constitutes, for example, a gyro-sensor that performs angular velocity detection using the quartz vibrator 113 formed in the sensing portion 111.

An operation of the physical quantity sensor will be described below.

When driving signals (carrier waves) different in phase by 180 degrees are applied to the driving electrodes 119a, 119b of the first driving piece 114 and the driving electrodes 119a, 119b of the second driving piece 115, the first and second driving pieces 114, 115 vibrate in left and right directions of the sheet of FIG. 7 and the detection piece 116 is substantially in a stationary state. In this case, when the angular velocity around an axis perpendicular to the surface of the sensor substrate 110 is applied, the detection piece 116 vibrates in the left and right directions of the sheet of FIG. 7 in accordance with the angular velocity. Accordingly, electric charges are generated in the detection piece 116 based on a piezoelectric effect and are outputted via the detection electrodes 121a, 121b. The sensor output based on the generation of the electric charges provides a sensor signal and the angular velocity is detected.

The angular velocity is detectable in this way. In this connection, because the cap layer 150 is made of a quartz substrate serving as a piezoelectric substrate, a joint-caused distortion is generated in the joint which joints the cap layer 150 and the sensor substrate 110 via the metal joint 161. Because of this joint-caused distortion, electric charges are induced in the cap layer 150. In general, as shown in FIG. 4, when pressure is applied to a quartz substrate 100, electric charges are generated in front and rear sides of the quartz substrate 100. As shown in FIG. 4, when the pressure is applied to the rear surface, negative electric charges are induced in the rear side having a compressive stress and positive electric charges are induced in the front side having a tensile stress. When the quartz substrate 100 is pulled from the rear surface, negative electric charges are induced in the front side and positive electric charges are induced in the rear side. In the quartz vibrator 113, the driving electrodes 119a, 119b, 120a, 120b are attached to the first driving piece 114 and the second driving piece 115, for voltage application. Accordingly, by using an inverse piezoelectric effect to vibrate the first driving piece 114 and the second driving piece 115, it becomes possible to vibrate at an intended frequency. In this regard, however, when the cap layer 150 is also made of a quartz substrate, the joint-caused distortion generates electric charges.

In this connection, the physical quantity sensor of the present embodiment includes the electric charge extraction wiring 180 by which the electric charges induced in the cap layer 150 are extracted to the outside of the physical quantity sensor via the metal joint 161. Therefore, the influence of the electric charges resulting from the joint-caused distortion on the sensor can be suppressed and the deterioration of sensor accuracy can be suppressed.

### Modification of Second Embodiment

The present embodiment is a modification of the second embodiment in structures of the electric charge extraction wiring 180. With regard to other points, the present embodiment is substantially the same as the second embodiment. A difference from the second embodiment will be described.

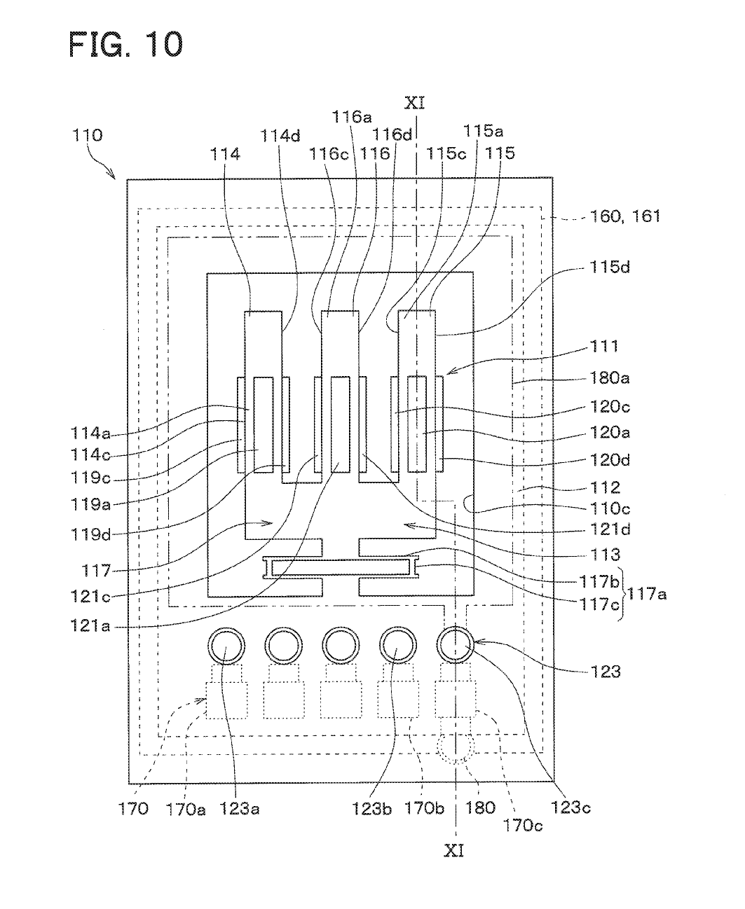

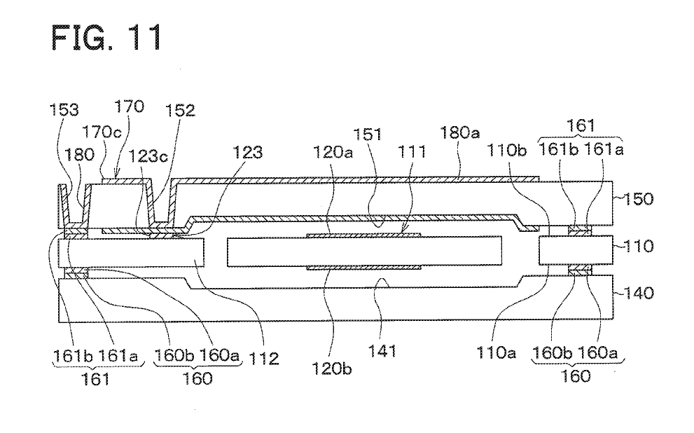

As shown in FIGS. 10 and 11, the electric charge extraction wiring 180 extends over, in the cap layer 150, the position corresponding to the sensing portion 111. Specifically, as shown by two-dotted dashed line in FIG. 11, the electric charge extraction wiring 180 is disposed on a region larger than a region that corresponds to the sensing portion 111 and the groove 110c and the electric charge extraction wiring 180 is connected to the ground pad 170c.

The electric charge extraction wiring 180 is disposed on both of the front and rear surfaces of the cap layer 150, that is, on a sensor substrate side surface and an opposite surface. The electric charge extraction wiring 180 disposed on both of the front and rear surfaces are opposed to each other and have the same pattern.

Moreover, when the electric charge extraction wiring 180 is formed to cover, of the cap layer 150, a portion corresponding to the sensing portion 111 and is connected to the ground pad 170c having the ground potential, it becomes possible to provide a shield effect against noise and the like. Additionally, because the electric charge extraction wirings 180 disposed on both of the front and rear surfaces have the same pattern, the positive charges and the negative charges generated in the front surface and the rear surfaces can be extracted and coupled to each other at the ground pad 170 and cancelled out. Accordingly, the sensor accuracy can further improve.

### Other Modification of the Second Embodiment

Embodiments are not limited to those illustrated above. Various modifications are possible within the spirit and scope of the present disclosure.

For example, although the physical quantity sensor, in particular, the gyro sensor, is illustrated in the above embodiments as an example of an oscillation device including a quartz vibrator, this is merely an example. Technical ideas of the present disclosure are applicable to other physical quantity sensor than the gyro sensor, for example, an acceleration sensor. Structures of the quartz vibrator are not limited to those illustrated in the above embodiments. For example, the physical quantity sensor may be a surface acoustic wave (SAW) element or the like and detect a physical quantity through generating SAW on a surface of a sensor substrate. Additionally, the oscillation device is not limited to physical quantity sensors but may be a crystal oscillator or the like. For example, the technical ideas are applicable to an oscillation device in which a vibration substrate with a vibrator made of a quartz substrate is jointed, via a metal joint, to a support substrate and a cap layer made of a quartz substrate.

In the above embodiments, the base portion 117 is provided with the vibration proof portion 117a. Alternatively, the vibration proof portion 117a may be omitted.

### Third Embodiment

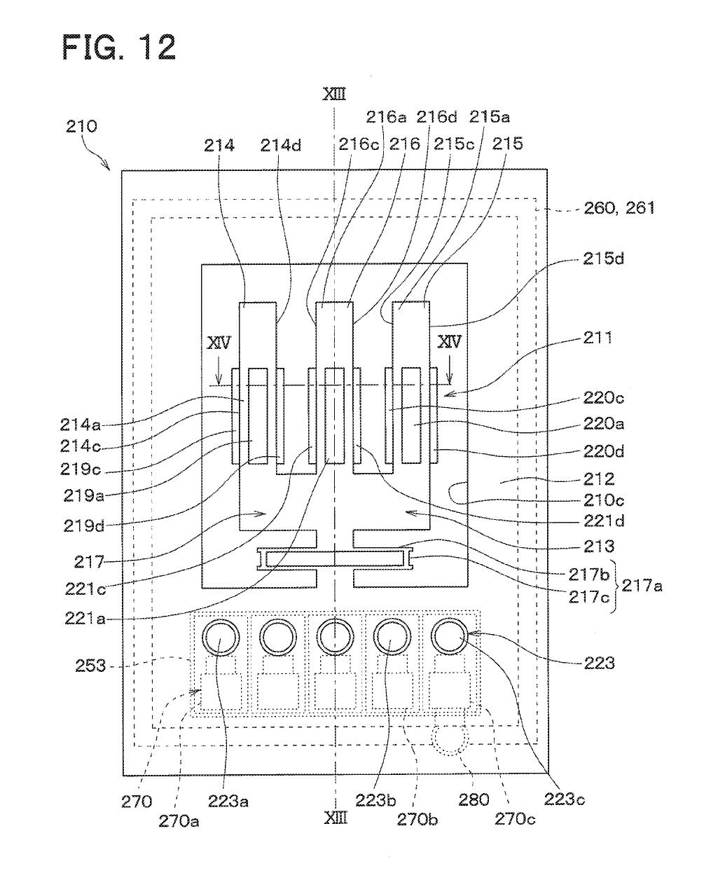

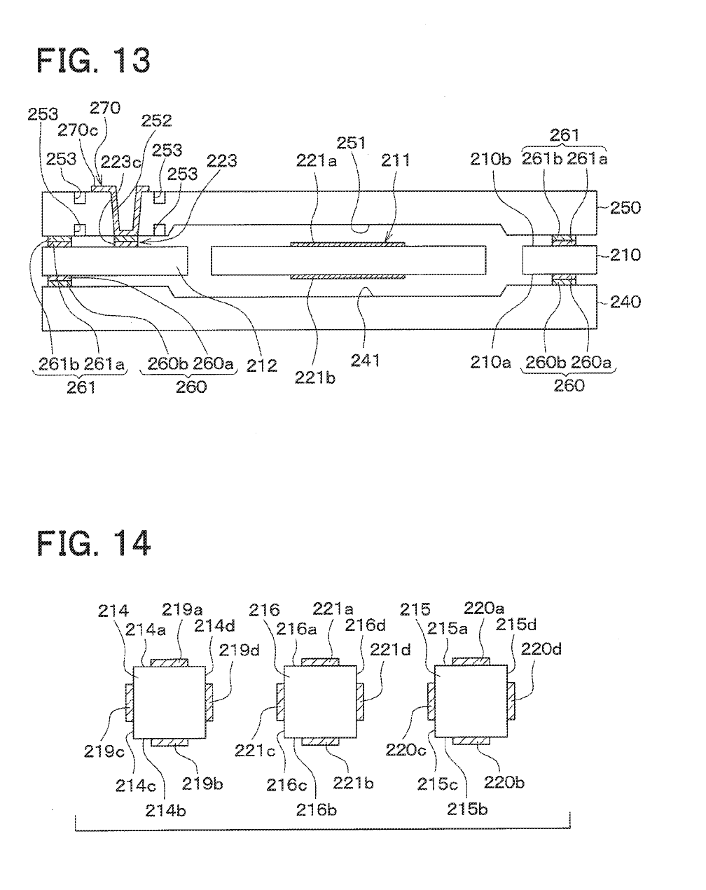

A third embodiment will be described with reference to FIG. 12 to FIG. 14. As shown in FIG. 12 and FIG. 13, a physical quantity sensor has a WLP structure including a sensor substrate 210, a support substrate 240 and a cap layer 250. A first surface of the sensor substrate 210 is called a rear surface 210a. A second surface opposite to the first surface is called a front surface 210b. The support substrate 240 is jointed to the rear surface 210a of the sensor substrate 210 via a metal joint 260. The cap layer 250 is jointed to the front surface 210b of the sensor substrate 210 via a metal joint 261. The sensor substrate 210 is disposed between the support substrate 240 and the cap layer 250 to form a vacuum chamber inside of which a sensing portion 211 is disposed. In the present embodiment, all of the sensor substrate 210, the support substrate 240 and the cap layer 250 are made from quartz substrates, which are piezoelectric substrates. However, it may be sufficient that at least the sensor substrate 210 and the cap layer 250 be made from quartz substrates. The support substrate 240 may be made of other materials such as glass.

As shown in FIG. 12, the sensor substrate 210 includes the sensing portion 211 and a peripheral portion 212 surrounding a periphery of the sensing portion 211. The sensing portion 211 includes a quartz vibrator 213. In the present embodiment, the quartz vibrator 213 is a tripod turning fork type. However, the quartz vibrator 213 may have other structures including known ones, such as a T turning fork type and an H turning fork type.

The sensing portion 211 is formed by performing a known micro-machine processing on the sensor substrate 210 to form a groove 210c and separating the quartz vibrator 213 from the peripheral portion 212.

The quartz vibrator 213 is constructed such that a first driving piece 214, a second driving piece 215 and a detection piece 216 are supported by a base portion 217 and that the base portion 217 serves as a coupling portion to couple the first driving piece 214, the second driving piece 215 and the detection piece 216 to the peripheral portion 212. Specifically, the quartz vibrator 213 is a tripod turning fork type in which the first and second driving pieces 214, 215 and the detection piece 216 are arranged to protrude from the base portion 217 in the same direction and the detection piece 216 is disposed between the first and second driving pieces 214, 215.

The base portion 217 is formed with a vibration proof portion 217a for absorbing disturbance vibration. The vibration proof portion 217a includes two beam portions 217b and a connection portion 217c connecting the two beam portions 217b. A longitudinal direction of the two beam portions 217b is perpendicular to a longitudinal direction of the first driving piece 214, the second driving piece 215 and the detection piece 216. In this structure, when the disturbance vibration is generated, the beam portions 217b are bent to absorb the disturbance vibration, thereby suppressing an influence on the first driving piece 214, the second driving piece 215 and the detection piece 216.

As shown in FIG. 14, the first driving piece 214 is rectangular in cross section and has a front surface 214a, a rear surface 214b and side surfaces 214c, 214d. The second driving piece 215 is rectangular in cross section and has a front surface 215a, a rear surface 215b and side surfaces 215c, 215d. The detection piece 216 is rectangular in cross section and has a front surface 216a and a rear surface 216b and side surfaces 216c, 216d. The surfaces 214a, 215a, 216a are parallel to a plane direction of the sensor substrate 210.

A driving electrode 219a is formed on the front surface 214a of the first driving piece 214. A driving electrode 219b is formed on the rear surface 214b. Common electrodes 219c, 219d are formed on the side surfaces 214c, 214d. Likewise, a driving electrode 220a is formed on the front surface 215a of the second driving piece 215. A driving electrode 220b is formed on the rear surface 215b. Common electrodes 220c, 220d are formed on the side surfaces 215c, 215d. Additionally, a detection electrode 221a is formed on the front surface 216a of the detection piece 216. A detection electrode 221b is formed on the rear surface 216b. Common electrodes 221c, 221d are formed on the side surfaces 216c, 216d.

In the present embodiment, the sensing portion 211 is constructed to include the first and, second driving pieces 214, 215, the detection piece 216, the driving electrodes 219a, 219b, 220a, 220b, the detection electrodes 221a, 221b, and the common electrodes 219c, 219d, 220c, 220d, 221c, 221d.

As shown in FIG. 12, the peripheral portion 212 is formed with multiple pad connection portions 223 which are electrically connected via wiring layers or the like (not shown) to the driving electrodes 219a, 219b, 220a, 220b, the detection electrodes 221a , 221 b, the common electrodes 219c, 219d, 220c, 220d, 221c, 221d.

The pad connection portions 223 include a power supply pad connection portion 223a for driving voltage application, an output pad connection portion 223b for sensor output, and a ground pad connection portion 223c for ground electric potential application. The respective pad connection portions 223 are connected to wiring patterns led form the above described various electrodes 219a to 219d, 220a to 220d, 221a to 221d. For example, the respective pad connection portions 223 are part of wiring patterns.

For example, the driving electrodes 219a, 219b, 220a, 220b are connected to the power supply pad connection portions 223a. The detection electrodes 221a, 221b are connected to the output pad connection portions 223b.

The common electrodes 219c, 219d, 220c, 220d, 221c, 221d are connected to the ground pad connection portion 223c. In FIG. 212, each portion of the sensor substrate 210 is shown by solid line and portions of the cap layer 250 are shown by broken line. The number of pad connection portions 223 shown in the drawings is merely an example. The number is not limited to those shown in the drawings.

A joint pattern 260a constituting part of the metal joint 260 is formed on the rear surface 210a of the sensor substrate 210 so as to surround the sensing portion 211 by one round. A joint pattern 261a constituting part of the metal joint 261 is formed on the front surface 210b of the sensor substrate 210 so as to surround the sensing portion 211 by one round. These joint patterns 260a, 260b are made of a metal material which provides metal eutectic bonding. The metal material is, for example, gold (Au), copper (Cu) etc.

The support substrate 240 is made of, for example, a quartz substrate. A cavity 241 is formed on, of a surface of the support substrate 240 on a sensor substrate 210 side, a portion corresponding to the sensing portion 211. This portion is inside a portion corresponding to the peripheral portion 212. Because of the cavity 241, the quartz vibrator 213 is prevented from contacting the support substrate 240. The joint pattern 260b constituting part of the metal joint 260 is formed on, of the support substrate 240, a portion corresponding to the peripheral portion 212 so that the joint pattern 260b surrounds the sensing portion 211 by one round. The joint pattern 260b is made of, for example, a metal material providing metal eutectic bonding and is formed using, for example, gold, copper etc. The joint pattern 260b has the same pattern as the joint pattern 260a formed on the rear surface 210a of the sensor substrate 210. By metal-jointing the joint patterns 260a, 260b, the metal joint 260 is formed and the joint between the support substrate 240 and the sensor substrate 210 is made

The cap layer 250 is made of, for example, a quartz substrate. A cavity 251 is formed on, of a surface of the cap layer 250 on a sensor substrate 210 side, a portion corresponding to the sensing portion 211. This portion is inside other portions corresponding to the peripheral portion 212. Because of the cavity 251, the quartz vibrator 213 is prevented from contacting the cap layer 250. The joint pattern 261b constituting part of the metal joint 261 is formed on, of the cap layer 250, a portion corresponding to the peripheral portion 212 so that the joint pattern 261b surrounds the sensing portion 211 by one round. The joint pattern 261b is made of, for example, a metal material providing metal eutectic bonding and is formed using, for example, gold, copper etc. The joint pattern 261b has the same pattern as the joint pattern 261a formed on the front surface 210b of the sensor substrate 210. By metal-jointing the joint patterns 261a, 261b, the metal joint 261 is formed and the joint between the cap layer 250 and the sensor substrate 210 is made.

A through-hole 252 is formed in the cap layer 250 at a position corresponding to each pad connection portion 223. A pad 270 extends from an inside of the through-hole 252 to a surface of the cap layer 250 on an opposite side from the sensor substrate 210. The pads 270 correspond to respective pad connection portions 223 and include a power supply pad 270a for voltage application, an output pad 270b for sensor output, and the ground pad 270c for ground electric potential application. The pads 270 are separated from one another and electrically connected to corresponding pad connection portions 223. Each pad 270 is electrically connected to a corresponding pad connection portion 223.

The pad 270 is formed by, for example, forming the through-hole 252 by etching the cap layer 250 or the like, and then, forming a conductive layer made of an electrode material such as aluminum (Al) or the like on a region including the inside of the through-hole 252. The pads 270 may be formed before or after jointing the cap layer 250 and the sensor substrate 210.

A groove 253 is formed on the cap layer 250 so as to surround each pad 270. The groove 253 is formed on both of the front surface and the rear surface of the cap layer 250. The front surface faces the sensor substrate 210 and is opposite to the rear surface. The grooves 253 on the first and second surfaces have the same layout when viewed in a direction perpendicular to the surface of the cap layer 250. The grooves 253 are formed on an outside of the cavity 251 and on an inside of the metal joint 261. In the present embodiment, the groove 253 surrounds each pad 270 one by one, while collectively surrounding all of the pads 270.

The physical quantity sensor of the present embodiment has the above-described structure. This physical quantity sensor constitutes, for example, a gyro-sensor that performs angular velocity detection using the quartz vibrator 213 formed in the sensing portion 211. An operation of the physical quantity sensor will be described below.

When driving signals (carrier waves) different in phase by 180 degrees are applied to the driving electrodes 219a, 219b of the first driving piece 214 and the driving electrodes 220a, 220b of the second driving piece 215, the first and second driving pieces 214, 215 vibrate in left and right directions of the sheet of FIG. 12 and the detection piece 216 is substantially in a stationary state. In this case, when the angular velocity around an axis perpendicular to the surface of the sensor substrate 210 is applied, the detection piece 216 vibrates in the left and right directions of the sheet of FIG. 12 in accordance with the angular velocity. Accordingly, electric charges are generated in the detection piece 216 based on a piezoelectric effect and are outputted via the detection electrodes 221a, 221b. The sensor output based on the generation of the electric charges provides a sensor signal and the angular velocity is detected.

The angular velocity is detectable in the above way. Incidentally, because the cap layer 250 is made of a quartz substrate acting as a piezoelectric substrate, the cap layer 250 functions as a diaphragm and the stress is easily applied to the electrical connection portion between the cap layer 250 and the sensor substrate 210. In particular, when the vacuum chamber is provided in the physical quantity sensor having the WLP structure, its outside has an air pressure and a stress caused by a strain resulting from a pressure difference is generated. Because of this stress, electric charges are induced in the cap layer 250.

In general, as shown in FIG. 4, when pressure is applied to a quartz substrate 100, electric charges are generated in front and rear sides of the quartz substrate 100. As shown in FIG. 4, when the pressure is applied to the rear surface, negative electric charges are induced in the rear side having a compressive stress and positive electric charges are induced in the front side having a tensile stress. When the quartz substrate 100 is pulled from the rear surface, negative electric charges are induced in the front side and positive electric charges are induced in the rear side. In the quartz vibrator 213, the driving electrodes 219a, 219b, 220a, 220b are attached to the first driving piece 214 and the second driving piece 215, for voltage application. Accordingly, by using an inverse piezoelectric effect to vibrate the first driving piece 214 and the second driving piece 215, it becomes possible to vibrate at an intended frequency. In this regard, however, when the cap layer 250 is also made of a quartz substrate, the joint-caused distortion generates electric charges. The electric charges may influence the sensor signal and may deteriorate sensor accuracy. When the cavity 251 is formed in the cap layer 250 and part of the cap layer 250 is thin, the cap layer 250 in particular can easily function as a diaphragm and electric charges can be easily induced.

For addressing this, in the present embodiment, the grooves 253 are formed on an inside of the metal joint 261. The grooves 253 are disposed on the front sand surfaces of the cap layer 250 so as to surround the pads 270. Thus, even if the cap layer 250 functions as a diaphragm, portions surrounded by the grooves 253 are hardly influenced by the stress. Therefore, the electric charges are hardly induced in the portions surrounded by the grooves 253, and accordingly, it becomes possible to suppress the influence of the sensor signal and the deterioration of the sensor accuracy.

### Modification of Third Embodiment

The present embodiment is a modification of the third embodiment in structures of cavities 241, 251. With regard to other points, the present embodiment is substantially the same as the third embodiment. A difference from the third embodiment will be described.

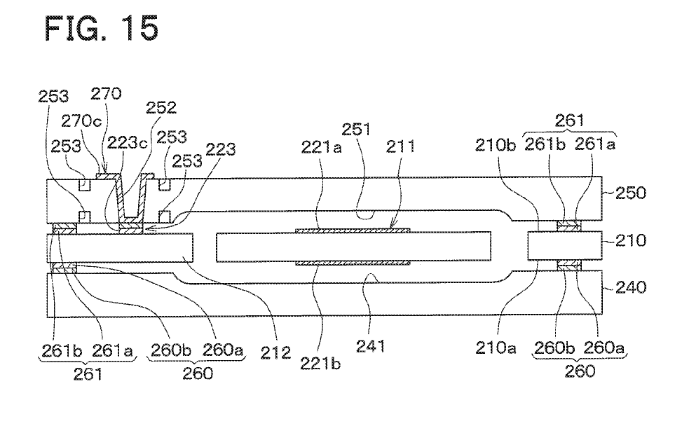

As shown in FIG. 15, a boundary between an inner peripheral surface and a bottom surface of the cavity 241 of the support substrate 240 is rounded (round shape). Likewise, a boundary between an inner peripheral surface and a bottom surface of the cavity 251 of the cap layer 250 is rounded (round shape).

Because of the round shape of the boundary between the inner peripheral surface and the bottom surface of the cavity 241, 251, stress concentration at this boundary can be relaxed. Additionally, forces applied to joints between the sensor substrate 210 and the support substrate 240 and between the sensor substrate 210 and the cap layer 250, specifically, forces applied to the metal joints 260, 261, can be reduced. Therefore, it becomes possible to further suppress the influence of the stress on the portions surrounded by the grooves 253. The advantages of the third embodiments are enhanced.

### Other Modifications of Third Embodiment

Embodiments are not limited to those illustrated above. Various modifications are possible within the spirit and scope of the present disclosure.

For example, although the physical quantity sensor, in particular, the gyro sensor, is illustrated in the above embodiments as an example of an oscillation device including a quartz vibrator, this is merely an example. Technical ideas of the present disclosure are applicable to other physical quantity sensor than the gyro sensor, for example, an acceleration sensor. Structures of the quartz vibrator are not limited to those illustrated in the above embodiments. For example, the physical quantity sensor may be a surface acoustic wave (SAW) element or the like and detect a physical quantity through generating SAW on a surface of a sensor substrate. Additionally, the oscillation device is not limited to physical quantity sensors but may be a crystal oscillator or the like. For example, technical ideas of the present disclosure are applicable to an oscillation device in which a support substrate and a cap layer which is made of a quartz substrate are jointed to a vibration substrate which is made of a quartz substrate and includes a vibrator.

In the above embodiments, the base portion 217 is provided with the vibration proof portion 217a. Alternatively, the vibration proof portion 217a may be omitted.

In the above embodiments, the groove 253 surrounds the pad 270 one by one while surrounding all of the pads 270. This is however merely an example. In a modification, the groove 253 may collectively surround all of the pads 270. In another modification, the grooves 253, respectively, may surround the pads 270 one by one.

Because sensor accuracy is influenced by, in particular, the power supply pad 270a and the output pad 270b, it may suffice that at least the power supply pad 270a and the output pad 270b be surrounded by the groove 253.

The shape of the groove 253 is not limited to a particular shape. Any shapes may be possible. For example, although the groove 253 surrounding the pad 270 has a quadrangular shape, the groove 253 may have other shapes such as a rounded-corner quadrangular shape, a elliptic shape and the like.

In the above embodiments, the support substrate 240 and the cap layer 250 are jointed to the sensor substrate 210 via the metal joints 260, 261. However, the joint is not required to be made of metal. The joint may be made of other joint materials such as adhesive.

What is claimed is:

1. An oscillation device comprising:
a vibrator made of a quartz substrate and configured to vibrate based on voltage application;
a vibration substrate coupled to the vibrator and including a peripheral portion surrounding a periphery of the vibrator;
a support substrate jointed to the vibration substrate at the peripheral portion of the vibration substrate;
a cap layer disposed on an opposite side of the vibration substrate from the support substrate, jointed to the vibration substrate at the peripheral portion of the vibration substrate via a joint, and provided with at least one pad electrically connected to the vibration substrate; and
at least one conductor pattern opposed to the pad, formed on a vibration substrate side surface of the cap layer, and electrically connected to the pad.

2. A physical quantity sensor comprising
the oscillation device recited in claim 1,
wherein:
the sensor substrate constitutes a sensing portion configured to displace according to a physical quantity applied to the vibrator;
the at least one pad includes
a power supply pad that applies a voltage to the vibrator;
an output pad that outputs a detection signal corresponding to the physical quantity according to displacement of the vibrator, and
a ground pad that is connected to a ground electric potential point of the sensor substrate; and
the at least one conductor pattern includes
a power supply pattern opposed to the power supply pad and electrically connected to the power supply pad,
an output pattern opposed to the output pad and electrically connected to the output pad, and
a ground pattern opposed to the ground pad and electrically connected to the ground pad.

3. The physical quantity sensor according to claim 2, wherein:
the cap layer has a through hole; and
at least one of the pads is electrically connected to at least one of the conductor patterns through the through hole.

4. The physical quantity sensor according to claim 2, wherein:
the cap layer has a first surface on a sensor substrate side and a second surface opposite to the first surface;
a first cover pattern is formed on, of the first surfaces of the cap layer, a portion corresponding to the vibrator; and
a second cover pattern is formed on, of the second surfaces of the cap layer, a portion corresponding to the vibrator and is electrically connected to the first cover pattern.

5. The physical quantity sensor according to claim 4, wherein:
the first cover pattern and the second cover pattern are electrically connected to each other in such manner that:
the first cover pattern, which is disposed on the sensor substrate side of the cap layer, is connected to at least one of the conductor patterns; and
the second cover pattern, which is disposed on an opposite side of the cap layer from the sensor substrate, is connected to at least one of the pads.

6. The physical quantity sensor according to claim 5, wherein
the first and second cover patterns are electrically connected to the ground pad and the ground pattern.

7. The oscillation device according to claim 1, further comprising:
a vibration proof portion disposed at a connection portion between the vibrator and the peripheral portion to absorb disturbance vibration.

8. An oscillation device comprising:
a vibrator made of a quartz substrate and configured to vibrate based on voltage application;
a vibration substrate coupled to the vibrator and including a peripheral portion surrounding a periphery of the vibrator;
a support substrate jointed to the vibration substrate at the peripheral portion of the vibration substrate;
a cap layer disposed on an opposite side of the vibration substrate from the support substrate, jointed to the vibration substrate at the peripheral portion of the vibration substrate via a metal joint, and provided with at least one pad electrically connected to the vibration substrate; and
an electric charge extraction wiring connected to the metal joint to extract electric charges in the metal joint.

9. The oscillation device according to claim 8, wherein:
the electric charge extraction wiring is disposed on the cap layer.

10. The oscillation device according to claim 9, wherein:
the cap layer has a through hole;
the electric charge extraction wiring is disposed inside the though hole.

11. The oscillation device according to claim 9, wherein:
the electric charge extraction wiring is connected to a ground electric potential part.

12. A physical quantity sensor comprising:
the oscillation device recited in claim 8,
wherein:
the sensor substrate constitutes a sensing portion configured to displace according to a physical quantity applied to the vibrator;
the at least one pad includes
a power supply pad that applies a voltage to the vibrator,
an output pad that outputs a detection signal corresponding to the physical quantity according to displacement of the vibrator, and
a ground pad that is connected to a ground electric potential point of the sensor substrate; and
the electric charge extraction wiring is connected to the ground pad.

13. The physical quantity sensor according to claim 12, wherein
a patterned conductive layer on a surface of the cap layer provides the power supply pad, the output pad, the ground pad and the electric charge extraction wiring; and
the ground pad and the electric charge extraction wiring are continuous.

14. The physical quantity sensor according to claim 12, further comprising
a wiring pattern disposed on at least one of a first surface or a second surface of the cap layer and covering a portion corresponding to the vibrator,
wherein the first surface of the cap layer faces the sensor substrate and is opposite to the second surface of the cap layer.

15. The physical quantity sensor according to claim 12, further comprising:
a vibration proof portion disposed at a connection portion between the vibrator and the peripheral portion to absorb disturbance vibration.

16. An oscillation device comprising:
a vibrator made of a quartz substrate and configured to vibrate based on voltage application;
a vibration substrate coupled to the vibrator and including a peripheral portion surrounding a periphery of the vibrator;
a support substrate jointed to the vibration substrate at the peripheral portion of the vibration substrate;
a cap layer disposed on an opposite side of the vibration substrate from the support substrate, jointed to the vibration substrate at the peripheral portion of the vibration substrate via a joint, and provided with at least one pad electrically connected to the vibration substrate; and
a groove formed on each of a first surface and a second surface of the cap layer, wherein the first surface of the cap layer faces the vibration substrate and is opposite to the second surface, wherein the groove is disposed on an inside of the joint and surrounds the pad.

17. A physical quantity sensor comprising:
the oscillation device recited in claim 16,
wherein:
the sensor substrate constitutes a sensing portion configured to displace according to a physical quantity applied to the vibrator;
the at least one pad includes
a power supply pad that applies a voltage to the vibrator,
an output pad that outputs a detection signal corresponding to the physical quantity according to displacement of the vibrator, and
a ground pad that is connected to a ground electric potential point of the sensor substrate; and
the groove surrounds at least the power supply pad and the output pad.

18. The physical quantity sensor according to claim 17, wherein:
the groove surrounds the power supply pad and the output pad one by one.

19. The physical quantity sensor according to claim 17, wherein:
the groove surrounds all of the power supply pad, the output pad and the ground pad.

20. The physical quantity sensor according to claim 17, wherein
the groove surrounds the power supply pad, the output pad and the ground pad one by one, while collectively surrounding all of the power supply pad, the output pad and the ground pad.

21. The physical quantity sensor according to claim 17, wherein
the first surface of the cap layer has a cavity at a position that faces the vibrator,
a boundary of an inner peripheral surface and an bottom surface of the cavity is rounded.

22. The physical quantity sensor according to claim 17, further comprising
a vibration proof portion disposed at a connection portion between the vibrator and the peripheral portion to absorb disturbance vibration.
